(19) United States
(12) Patent Application Publication
(10) Pub. No.: US 2014/0357053 A1
(43) Pub. Date: Dec. 4, 2014

(54) Method for Preparing Composite Substrate Used For GaN Growth

(71) Applicants: Yongjian Sun, Beijing (CN); Guoyi Zhang, Beijing (CN); Yuzhen Tong, Beijing (CN)

(72) Inventors: Yongjian Sun, Beijing (CN); Guoyi Zhang, Beijing (CN); Yuzhen Tong, Beijing (CN)

(73) Assignee: Sino Nitride Semiconductor Co., LTD, DongGuan (CN)

(21) Appl. No.: 14/373,310

(22) PCT Filed: May 22, 2012
(86) PCT No.: PCT/CN2012/075856

§ 371 Date: Jul. 18, 2014

(30) Foreign Application Priority Data
Mar. 14, 2012 (CN) 201210068033.0

(51) Int. Cl. H01L 33/00

(52) U.S. Cl. CPC H01L 33/0079; H01L 33/0075
USPC 438/458

(57) ABSTRACT

A method for preparing a composite substrate for GaN growth includes: growing a GaN monocrystal epitaxial layer on a sapphire substrate, bonding the GaN epitaxial layer onto a temporary substrate, lifting off the sapphire substrate, bonding the GaN epitaxial layer on the temporary substrate with a thermally and electrically conducting substrate, shedding the temporary substrate, and obtaining the composite substrate in which the GaN layer having a surface of gallium polarity is bonded to the conducting substrate. If the GaN layer on the sapphire substrate is directly bonded to the conducting substrate, after the sapphire substrate is lifted off, a composite substrate in which a GaN epitaxial layer having a surface of nitrogen polarity is bonded to the conducting substrate. The disclosed composite substrates have homoepitaxy and improved crystal quality; they can be used for forming LED and other devices at greatly reduces costs.

### BACKGROUND OF THE INVENTION

The present application relates to optoelectronic semiconductor devices, and in particular, to manufacturing methods for fabricating such devices.

In recent years, III/V nitride materials, mainly GaN, InGaN, and AlGaN, have received much attention as semiconductor materials. The III/V nitride materials have direct band gaps that can be continuously varied from 1.9 to 6.2 eV, excellent physical and chemical stability, and high saturation electron mobility. They have become the preferred materials for optoelectronic devices such as laser devices and light-emitting diodes.

Due to a lack of GaN substrate, the present GaN-based semiconductor devices involves hetero-epitaxial growth of GaN layers on a substrate of a different material such as sapphire, SiC, and Si, wherein crystalline lattices of the GaN materials are highly mismatched to those of the substrate.

Among the above described substrate materials, sapphire is the most widely used. Sapphire substrate, however, is associated with the following problems: first, the large lattice mismatch and thermal stress between the epitaxially grown GaN and the sapphire substrate can produce high concentration of dislocations of about 10⁹ cm⁻², which seriously degrades the quality of GaN crystal, and reduces illumination efficiency and the lifespan of LED. Secondly, because sapphire is an insulator with an electrical resistivity greater than 10¹¹ Ωcm at room temperature, it is not suitable to be used for forming devices having vertical structures. Sapphire is usually only used to prepare N-type and P-type electrodes on the epitaxial layer, but it reduces effective lighting area, increases the lithography and etching processes during the fabrication of the devices, and reduces the material utilization. Moreover, sapphire has a poor thermal conductivity of about 0.25 W/(cm·K) at 1000° C., which significantly affects performances of GaN-based devices, especially the large-area and high-power devices in which heat dissipation is required. Furthermore, sapphire has a high hardness and its lattice has a 30 degree angle relative to the lattice of GaN crystal, it is difficult to obtain a cleavage plane of the InGaN epitaxial layer to obtain a cavity surface during the fabrication of GaN-based Laser Diode (LD).

Comparing to sapphire, a SiC substrate has smaller lattice mismatch to GaN. However, GaN—SiC hetero-epitaxial growth still generates misfit dislocations and thermal misfit dislocations. Moreover, SiC is expensive, making it unsuitable for many GaN-based optoelectronic devices. In recently years, Si has also been studied as a substrate for the epitaxial growth of GaN crystals. However, Si has cubic crystalline lattice while GaN has a hexagonal crystalline lattice. Si has a lattice mismatch to GaN even larger than sapphire/GaN, which makes it difficult to support epitaxial growth of GaN material. The GaN layer grown on Si substrates faces serious problems such as cracking; the crystal growth thickness usually cannot exceed 4 μm.

Recently, GaN mono-crystalline substrate has been developed for growing GaN optoelectronic devices. The GaN mono crystal s on the substrate allows homoepitaxial growth of GaN crystals and can improve the quality of epitaxially grown GaN crystal. Moreover, the good thermal conductivity of the GaN microcrystals allows the formation of vertical structure LED on such substrates. The properties of the devices are improved under large current injections. However, the high cost of the GaN mono-crystalline substrate severely restricts its usage in LED devices. While a 2 inch wide high power LED epitaxial sheet is typically less than 100 dollars, the price for a 2 inch wide GaN mono-crystalline substrate can reach 2000 dollars.

There is therefore a long-felt need for a substrate that can provide epitaxial growth of GaN crystals for fabricating optoelectronic devices without or minimizing the issues discussed above.

### SUMMARY OF THE INVENTION

The present application provides new types of composite substrates and associate methods for growing GaN crystals that can reduce or eliminate the above descried problems. The disclosed composite substrate includes a thermally and electrically conductive layer, and a mono-crystalline GaN layer on the thermally and electrically conductive layer.

The disclosed methods, materials, and structures enable homoepitaxial growth of GaN crystals on a substrate, improve the quality of the grown GaN crystals, and reduce cost. The disclosed methods, materials, and structures also allow vertical device structures being directly formed on the disclosed substrates.

The disclosed methods, materials, and structures can be used in the fabrication of a wide range of optoelectronic devices.

The composite substrate of the present invention can be directly used for the epitaxial-growth of GaN epitaxial layers, and for the preparation of a vertical structure LED device. The disclosed methods have the one or more following additional advantages compared with conventional technologies:

First, the disclosed methods are much improved over the most commonly used GaN epitaxial growth on sapphire substrates. The sapphire substrate has low electrical and thermal conductivities, which makes difficult or impossible for growing a vertical structure LED device on such substrate. The planar structure LEDs grown on sapphire substrates do not dissipate heat well and are not suitable for high power devices. Additionally, sapphire substrate has a different lattice from GaN, which affects the quality of GaN crystals grown on these substrates.

In contrast, the disclosed composite substrate has a GaN layer that enables homoepitaxial growth of GaN crystals with improved crystalline quality and thus increased quantum efficiency. Moreover, the composite substrate includes a thermally and electrically conductive layer, which allows the formation a vertical structure LED devices, which greatly increases device efficiency and device density compared to conventional sapphire-based technologies.

The disclosed composite substrate is also advantageous over the conventional Si and SiC substrates. Although these conventional substrates permit epitaxial growth vertical GaN device structures, the GaN crystal growth is heteroepitaxy, which affects crystalline quality of GaN. The lattice mismatch is especially severe for the Si substrate; AlGaN layers are often inserted between the epitaxy grown GaN crystal and the Si substrate to relax stress. The GaN crystal can hardly grow thicker than 3-4 μm on Silicon substrate. On the other hand, although the lattice constant of a SiC substrate is close to a GaN crystal, it is difficult to prepare SiC crystals, and costs are high. In comparison, the disclosed composite substrate enables homoepitaxial growth of GaN crystals, which offers superior crystalline quality and makes it suitable for a wide range of applications.

The disclosed composite substrate is also a significant improvement over mono-crystalline GaN substrate. Although both substrates provide homoepitaxial growth of GaN crystals, crystalline quality and thermal dissipation are greatly improved in the disclosed composite substrate by employing two substrate layers of different materials. By using a conductive layer and a thin mono-crystalline GaN substrate, the disclosed composite substrate significantly reduces material cost compared to mono-crystalline GaN substrates.

In summary, the disclosed composite substrate has a combination of advantageous properties of enabling homoepitaxial GaN growth, high and improved crystalline quality, compatibility with vertical structure devices, and greatly reduced cost. These advantages should enable the disclosed composite substrate for a wide range of device applications.

For preparing the composite substrate used for GaN growth, two kinds of methods are provided in the present invention, respectively for preparing a composite substrate having an upper surface with gallium polarity and a composite substrate having an upper surface with nitrogen polarity.

The first method for preparing a composite substrate having an upper surface gallium polarity, comprises the steps of:

1a) growing a GaN monocrystal epitaxial layer on a sapphire substrate;
1b) bonding the GaN monocrystal epitaxial layer grown on a sapphire substrate onto a temporary substrate with an epoxy-type instant adhesive, then lifting off the sapphire substrate by a laser lift-off method; and

1c) bonding the GaN monocrystal epitaxial layer on the temporary substrate with a thermally and electrically conducting substrate with a melting point greater than 1000° C., the epoxy-type instant adhesive will be carbonized at high temperature, shedding the temporary substrate, and so obtaining the composite substrate in which the GaN monocrystal epitaxial layer with gallium polarity facing up is bonded to the thermally and electrically conducting substrate, after surface cleaning.

In step 1a), the method for growing GaN can use the MOCVD method or HPVE method well-known in the art, or use the MOCVD method combined with the HPVE method. Usually first using the MOCVD method, then using the hydride vapor phase epitaxy (HPVE) method for growing GaN monocrystal.

The sapphire substrate can be a flat sapphire substrate or a patterned sapphire substrate. The patterned sapphire substrate is designed according to the structure of the reflecting layer in the composite substrate, obtained by preparing micron-scale or nano-scale periodic structural patterns on the surface of the sapphire substrate by lithography lift-off method. To the GaN monocrystal epitaxial layer grown by the patterned sapphire substrate and transferred onto the temporary substrate, the patterns of the sapphire substrate have been transferred onto the GaN layer successfully while being lifted off, which could be used as reflecting layer. But to the GaN monocrystal epitaxial layer grown by a flat sapphire substrate, the reflecting layer can be prepared by one of the following two methods:
I. After the GaN monocrystal epitaxial layer being transferred from the sapphire substrate onto the temporary substrate in step 1b), deposit a metal reflecting layer (with a thickness of less than 1 μm) on the surface of the GaN monocrystal by the deposition technique well-known in the art, and then conduct step 1c). In the finally prepared composite substrate with gallium polarity facing up, the reflecting layer is located on the bottom surface of the GaN monocrystal epitaxial layer.
II. In the process of GaN epitaxial-growth in step 1a) first growing a layer of GaN, then growing a layer of reflecting layer materials, preparing the layer of reflecting layer materials into micron-scale or nano-scale periodic structures (i.e. the reflecting layer structure) by lithography and dry etching technologies well-known in the art, requiring to expose the GaN surface at the spacing of these structures at the same time, and then growing GaN monocrystal continuously to the required thickness, and then conducting the step 1c). In the finally prepared composite substrate with gallium polarity facing up, the reflecting layer is located at the inner side of the GaN monocrystal epitaxial layer.

In the method II, the reflecting layer materials are required to have a refractive index different from that of GaN, a melting point greater than 1000° C., and can be grown by crystal or coating method, such as SiO2 and SiN. SiO₂ layer and SiN layer can be grown by Plasma Enhanced Chemical Vapor Deposition (PECVD) method, with a thickness of 0.2 μm˜2 μm.

In the step 1b), the epoxy-type instant adhesive can be 502 adhesive for example, the temporary substrate can be metal temporary substrate or Si monocrystal temporary substrate.

In the step 1c), the bonding method can use rigid or flexible medium to bond. The rigid bonding is that, without depositing any bonding metal, Van der Waals bonding the GaN epitaxial layer on the temporary substrate with a thermally and electrically conducting substrate directly, by a van der Waals force, at 500˜900° C., under pressure of 3 tons per square inch to 10 tons per square inch. As mentioned above, the rigid bonding requires the coefficient of thermal expansion difference between the materials of the thermally and electrically conductive layer and GaN to be within 10%, such as Si monocrystal substrate, SiC monocrystal substrate and AlSi crystal substrate.

The flexible medium bonding is that, depositing bonding metal on the surface to be bonded, and then bonding the GaN epitaxial layer on the temporary substrate with a thermally and electrically conducting substrate, at 200˜900° C., under pressure of 1 tons per square inch to 5 tons per square inch. The thickness of the bonding layer bonded by flexible medium preferably is 0.5˜5 μm, the bonding metal can be Au, W, Pd, Ni, and so on.

The second method for preparing a composite substrate having nitrogen polarity facing up, comprises the steps of:

2a) growing a GaN monocrystal epitaxial layer on a sapphire substrate;

2b) bonding the epitaxial layer grown on a sapphire substrate with the thermally and electrically conducting layer with a melting point greater than 1000° C.;

2c) lifting off the sapphire substrate by laser lift-off method, obtaining a composite substrate having nitrogen polarity facing up and with the GaN epitaxial layer bonded with the thermally and electrically conducting layer.

In step 2a), the method for growing GaN can use the MOCVD method or HPVE method well-known in the art, or use the MOCVD method combined with the HPVE method. Usually the MOCVD method is first used, followed by the HPVE method (hydride vapor phase epitaxy) for growing GaN monocrystal.

The GaN monocrystal epitaxial layer is grown on the plate sapphire substrate, to the composite substrate with a reflecting layer designed, before conducting step 2b), one of the following two methods can be used for preparing the reflecting layer:
A. Deposit a metal reflecting layer (with a thickness of less than 1 μm) on the surface of the GaN monocrystal epitaxial layer prepared by step 2a) by the deposition technique well-known in the art, and then conduct step 2b). In the finally prepared composite substrate having nitrogen polarity facing up, the reflecting layer is located on the bottom surface of the GaN monocrystal epitaxial layer.
B. In the process of GaN epitaxial-growth in step 2a), first growing a layer of GaN, then growing a layer of reflecting layer materials, preparing the layer of reflecting layer materials into micron-scale or nano-scale periodic structures (i.e. the reflecting layer structure) by lithography and dry etching technologies well-known in the art, requiring to expose the GaN surface at the spacing of these structures at the same time, and then growing GaN monocrystal continuously to the required thickness, and then conducting step 2b). In the finally prepared composite substrate with nitrogen polarity facing up, the reflecting layer is located on the inner side of the GaN monocrystal epitaxial layer.

In the method B, the reflecting layer materials are required to have a refractive index different from that of GaN, a melting point greater than 1000° C., can be grown by crystal or coating method, such as SiO₂ and SiN. SiO₂ layer and SiN layer can be grown by PECVD method, with a thickness of 0.2 μm˜2 μm.

In step 2b), the bonding method can use rigid or flexible medium to bond. The rigid bonding is that, without depositing any bonding metal, Van der Waals bonding the GaN monocrystal epitaxial layer on the sapphire substrate with a thermally and electrically conducting substrate directly, by a van der Waals force, at 500˜900° C., under pressure of 3 tons per square inch to 10 tons per square inch. As mentioned above, the rigid bonding requires the coefficient of thermal expansion difference between the materials of the thermally and electrically conductive layer and GaN is within 10%, such as Si monocrystal substrate, SiC monocrystal substrate and AlSi crystal substrate.

The flexible medium bonding is that, depositing bonding metal on the surface to be bonded, and then bonding the GaN epitaxial layer on the temporary substrate with a thermally and electrically conducting substrate, at 200˜900° C., under pressure of 1 tons per square inch to 5 tons per square inch. The thickness of the bonding layer bonded by flexible medium preferably is 0.5˜5 μm, the bonding metal can be Au, W, Pd, Ni and so on.

In sum, in the present disclosure teaches a kind of new composite substrate prepared by laser lift-off, bonding, micromachining and epitaxy techniques, which provides homoepitaxy required in GaN epitaxy, improved crystal quality. The disclosed composite substrate can be used to form vertical structure for LED. Further, the use of thin-layer GaN monocrystal significantly reduces cost, making disclosed more advantageous than conventional GaN substrate.

These and other aspects, their implementations and other features are described in detail in the drawings, the description and the claims.

### BRIEF DESCRIPTION OF THE DRAWINGS

FIG. 1 is a cross-sectional diagram of a composite substrate for GaN growth in accordance to the present invention.

FIG. 2 is a cross-sectional diagram of another composite substrate including a reflective layer in accordance to the present invention.

FIG. 3 is a cross-sectional diagram of another composite substrate including a reflective layer in accordance to the present invention.

FIG. 4 is a cross-sectional diagram of another composite substrate including a periodic grating or a periodic photonic lattice structures in the reflective layer.

FIGS. 5A-5B are perspective diagrams showing a reflective layer respectively having, on its surface, triangular pyramidal recesses (FIG. 5A) and cylindrical recess (FIG. 5B).

FIG. 6 is a schematic diagram showing the steps of bonding a Si substrate to a GaN crystal, and lifting off a sapphire substrate as described in Implementation Example 1.

FIG. 7 is a schematic diagram showing the step of bonding a WCu substrate to a GaN crystal and removing Si substrate from the GaN crystal at high temperature as described in Implementation Example 1.

FIGS. 8A-8D are cross-sectional diagrams showing the preparation of GaN/WCu, GaN/MoCu, and GaN/SiC composite substrates respectively described in Implementation Examples 2, 3, and 6.

FIGS. 9A-9B are cross-sectional diagrams showing the preparation of a GaN/MoCu composite substrate including a metal reflective layer as described in Implementation Example 4.

FIGS. 10A-10B are cross-sectional diagrams showing the preparation of a composite substrate in which a GaN layer is bonded with Si substrate through Van der Waals force as described in Implementation Example 5.

FIGS. 11A-11D are cross-sectional diagrams showing the preparation of a composite substrate in which the GaN layer is bonded with AlSi substrate through AuAu bond as described in Implementation Example 7.

FIG. 12 is a photograph of a composite substrate prepared by the presently disclosed method in which the mono-crystalline GaN layer is bonded with a metal substrate.

### DETAILED DESCRIPTION OF THE INVENTION

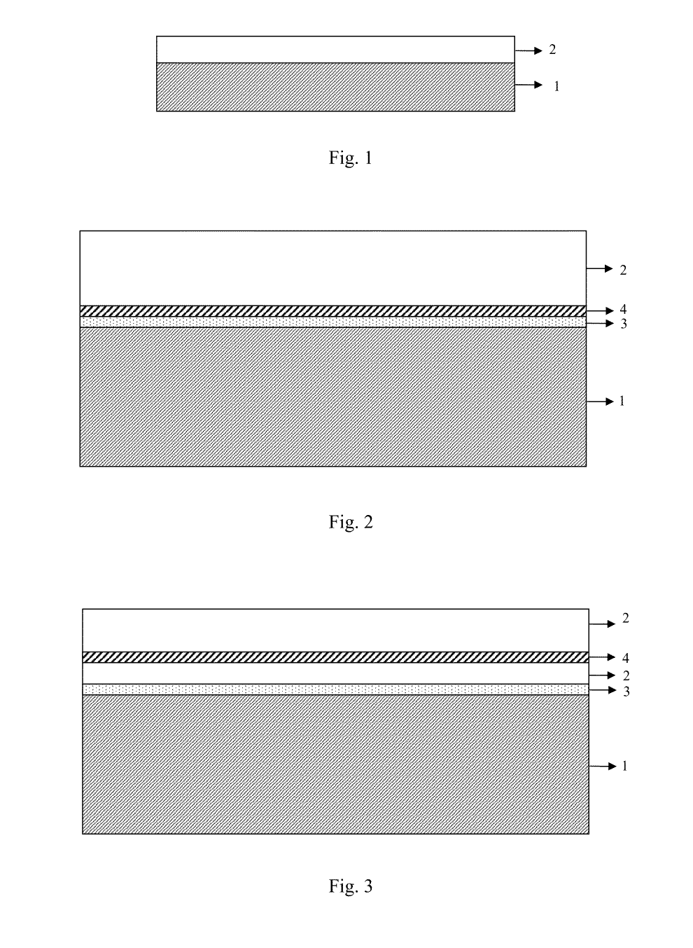

Referring to FIG. 1, a composite substrate includes a thermally and electrically conductive layer 1, and a mono-crystalline GaN layer 2 bonded on to the thermally and electrically conductive layer 1.

The thermally and electrically conductive layer has a thickness in range of 10˜3000 μm, preferably 50˜400 μm. Materials suitable for the thermally and electrically conductive layer 1 are required to have several characteristics: (1) a melting point greater than 1000° C., or nearly in solid state at 1000° C.; and (2) high thermal and high electrical conductivities.

Based on the above requirements, examples of materials suitable for the thermally and electrically conductive layer 1 include metal elements such as W, Ni, Mo, Pd, Au, and Cr, or alloys or quasi alloys of the above metals, or alloy of the above metals with Cu, such as WCu alloy, MoCu alloy, and NiCu alloy. Other materials suitable for the thermally and electrically conductive layer include Si crystalline, SiC crystalline, and AlSi crystalline.

The mono-crystalline GaN layer 2 has a thickness in a range of 0.1˜100 μm, preferably 1˜50 μm. The GaN crystal in the mono-crystalline GaN layer 2 is in the form of a mono crystal.

The thermally and electrically conductive layer 1 can be bonded with the mono-crystalline GaN layer 2 through rigid bonding or flexible bonding. If the bonding is a rigid van der Waals force bonding, the thermal expansion coefficient of the thermally and electrically conductive layer 1 should be close to (i.e. within 10%) the thermal expansion coefficient of the mono-crystalline GaN layer 2. The thermally and electrically conductive layer can also be bonded with the mono-crystalline GaN layer 2 through a flexible medium, which is required to have a melting point greater than 1000° C., and sufficient ductility to relax stress. Examples of such flexible medium includes a layer of Au—Au bonds, or bonds between W, Pd, Ni, or other high-temperature metals, with a layer thickness ranged 0.5˜5 μm. Such metallic medium bonding layer can relax the thermal stress produced by the different thermal expansions between the mono-crystalline GaN layer 2 and the thermally and electrically conductive layer 1. Thus, when bonded with the flexible medium in between, the thermal expansion coefficient of the thermally and electrically conductive layer 1 is not required to be close to that of the mono-crystalline GaN layer 2.

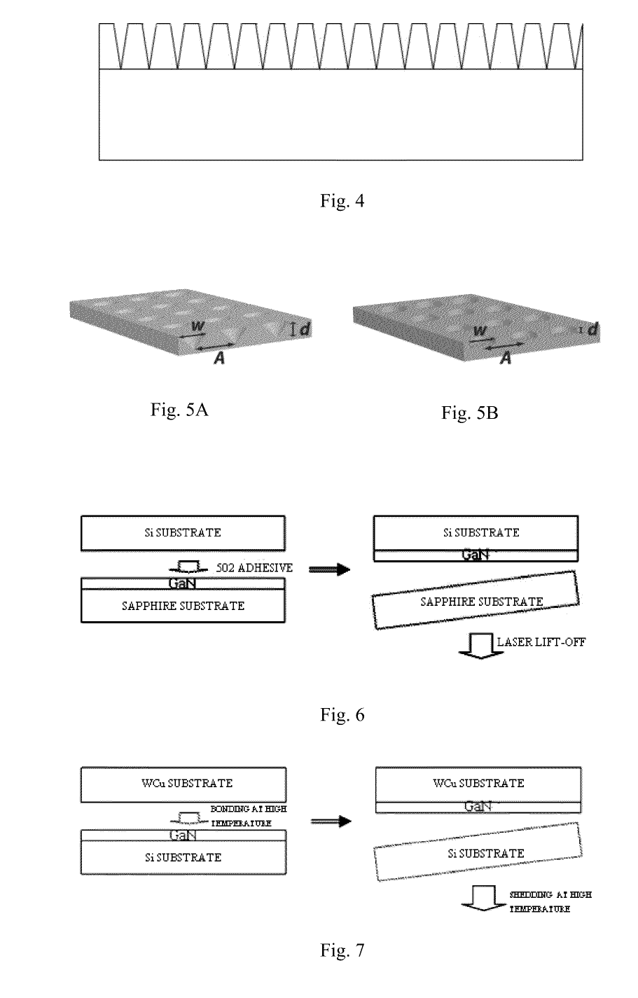

Furthermore, a composite substrate can include a reflective layer 4, located inside, in the lower portion, or at a lower surface of the mono-crystalline GaN layer 2. The reflective layer 4 can be sandwiched at the interface between the mono-crystalline GaN layer 2 and the thermally and electrically conductive layer 1. Referring to FIG. 2, the reflective layer 4 can also be located between a bonding layer 3 and the mono-crystalline GaN layer 2. The bonding layer 3 is positioned between the thermally and electrically conductive layer 1 and the reflective layer 4. As shown in FIG. 3, the reflective layer 4 can also be located inside or in the lower portion of the mono-crystalline GaN layer 2. If the reflective layer 4 is located at the side of the bonding layer that is close to the mono-crystalline GaN layer 2, the reflective layer 4 can be formed by a metallic material such as Pd, Cr, and so on. If the reflective layer is located inside or at the lower portion of the mono-crystalline GaN layer 2, the reflective layer 4 can be in a periodic or quasi-periodic structure, as shown in FIG. 4. Examples for such periodic or quasi-periodic structure include grating structures or photonic lattice structures.

The grating structures are micron-scale periodic structures. The photonic lattice structures are nano-scale periodic structures which can be periodic protrusions or recesses. The protrusions and the recesses can have conical shapes, cylindrical shapes, or triangular pyramidal shapes. The protrusions and the recesses can be disposed periodically, quasi-periodically, or aperiodic. FIG. 5A shows a reflective layer having triangular pyramidal recesses distributed periodically. FIG. 5B shows a reflective layer having cylindrical recesses distributed periodically. These micron-scale or nano-scale periodic structures can be 10 nm˜50 μm, preferably 200 nm˜10 μm. In FIGS. 5A and 5B, w and d are respectively the width and the depth of the recesses; A is the period or the mean distance between adjacent recesses, wherein A>w.

The micron-scale or nano-scale structures in the reflective layers are required to be heat-resistant, for example, having melting point greater than 1000° C. The materials forming the structures have a refractive index different from that of the microcrystalline GaN layer 2. For example, suitable materials include SiO₂ or SiN that can grow in a crystalline phase on the mono-crystalline GaN layer 2, or coated on or embedded in the mono-crystalline GaN layer 2. These materials have refractive indices different from the mono-crystalline GaN layer 2, and generate effective total internal reflections. The average refractive index at the interface between thermally and electrically conductive layer 1 and the mono-crystalline GaN layer 2 is effectively increased by the periodic structures.

In some embodiments, the periodic structures located at the lower portion or in the lower surface of the mono-crystalline GaN layer 2 are made of the same material as the mono-crystalline GaN layer 2. These periodic patterns can also reflect light and can act as reflective layers.

The reflective layer plays an important role on the GaN-based devices that are epitaxially grown on the disclosed composite substrate. In the light emitting devices, the light from active layer can usually be emitted in a 360 degree angular range. Without reflective layers, 40% of the emitted light can be absorbed by the thermally and electrically conductive layer, which presents a significant waste. The incorporation of the reflective layers to the disclosed composite substrate can thus increase light emission efficiency more than 30%.

The present disclosure is illustrated by the following implementation examples. It should be understood, however, that disclosed invention is not limited by the examples below. Other implementations, variations, modifications and enhancements to the described examples and implementations can be made without deviating from the spirit of the present invention.

### Implementation Example 1

### A Metal Composite Substrate without a Reflective Layer and Comprising a WCu Alloy Layer and a GaN Layer Bonded with Au—Au Bonds

In the first steps, a 4 μm thick GaN mono crystal is epitaxially grown on a 2 inch 430 μm thick sapphire substrate using Metal-organic Chemical Vapor Deposition (MOCVD). Next, a GaN crystal is grown to a crystal thickness of 10 μm using hydride vapor phase epitaxy (HVPE) technique.

In the second steps, referring to FIG. 6, a surface of the GaN mono crystal is bonded to a 2 inch 400 μm thick Si substrate using 502 instant adhesive. The Si substrate is used as a transfer and support substrate. The sapphire substrate is then lifted off from the GaN crystal using laser lift-off technology, leaving an assembly comprising a GaN mono crystal bonded on the Si substrate.

In the third steps, a 1 μm Au layer is deposited simultaneously on the surfaces of mono-crystalline GaN layer and the Si substrate 6, and the surfaces of a WCu alloy substrate. The WCu alloy substrate is then bonded to the surface of the GaN mono crystal via Au—Au bonding, as shown in FIG. 7, at 300° C. under a pressure of 5 tons for through 15 minutes. After bonding, the 502 instant adhesive is carbonized at high temperature, which allows Si substrate to separate from GaN/WCu composite substrate.

After surface cleaning, a GaN/WCu composite substrate is obtained. The composite substrate includes a 150 μm thick WCu alloy layer with a W:Cu mass ratio of 15:85. The WCu alloy layer is bonded with a layer of 10 μm thick GaN mono crystal layer by AuAu bond. The thickness of the bonding layer is 2 μm.

### Implementation Example 2

### A Metal Composite Substrate with a Reflective Layer and Comprising a WCu Alloy Layer and a GaN Layer Bonded with Au—Au Bonds

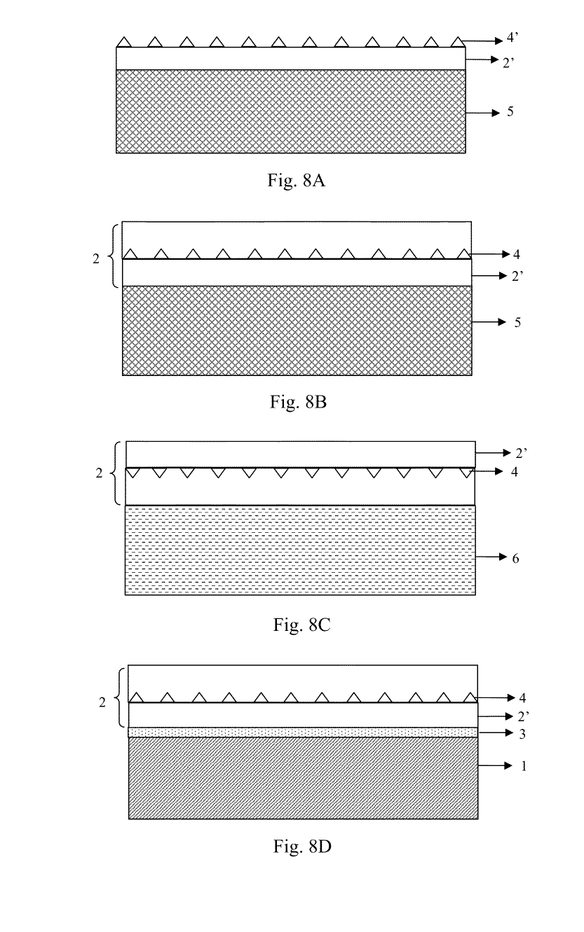

In the first steps, as shown in FIG. 8A, a GaN mono crystal thin film 2′ is epitaxially grown on a 2 inch 430 μm thick sapphire substrate 5 using MOCVD. The GaN mono crystal thin film 2′ is about 4 μm in thickness.

In the second steps, a 1 μm layer of SiO₂ thin film is grown on the surface of the GaN mono crystal layer using PECVD technology. The SiO₂ thin layer is then patterned with lithography and dry etched into periodic conical structures 4′ spaced by a period of about 3 μm, as shown in FIG. 8A. The conical structures 4′ have a base diameter of about 2.5 μm and a height about 1 μm. The surface of the GaN mono crystal thin film 2′ is exposed in the space between the conical structures 4′. The periodic conical structures 4′ form as a reflective layer 4.

In the third steps, as shown in FIG. 8B, a GaN crystal layer is continuously grown using HVPE technology on the surface of the GaN mono crystal thin film 2′ and the reflective layer 4 composed of periodic conical structures 4′. The newly grown GaN crystal and the GaN mono crystal thin film 2′ together forms a mono-crystalline GaN layer 2 having a total thickness of about 10 μm. The reflective layer 4 is embedded inside the mono-crystalline GaN layer 2.

In the fourth steps, as shown in FIG. 8C, the surface of the mono-crystalline GaN layer 2 is bonded with a 2 inch 400 μm thick Si substrate 6 by an instant adhesive. The Si substrate 6 is used as a transfer and support substrate. The sapphire substrate 5 is then lifted off by laser lift-off technology, leaving the mono-crystalline GaN layer 2 bonded to the Si substrate 6.

In the fifth steps, a 1 μm Au layer is deposited simultaneously on the surfaces of the mono-crystalline GaN layer 2 and the Si substrate 6, and the surfaces of a separate 150 μm thick WCu alloy layer (substrate) 1. The WCu alloy layer 1 is then bonded to the surface of the mono-crystalline GaN layer 2 via Au—Au bonding, as shown in FIG. 8D, at 300° C. under a pressure of 5 tons for through 15 minutes. After bonding, the instant adhesive is carbonized at high temperature, which allows Si substrate 6 to separate from GaN/WCu composite substrate.

At last, as shown in FIG. 8D, after surface cleaning, a composite substrate is obtained which includes a 150 μm thick WCu alloy layer 1 with a W:Cu mass ratio of 15:85. The WCu alloy layer 1 is bonded with a layer of 10 μm thick GaN mono crystal layer by Au—Au bond, wherein the bonding layer 3 is 2 μm in thickness. The reflective layer 4 is embedded in the mono-crystalline GaN layer 2 and is at 4 μm distance from the bonding layer 3. The reflective layer 4 includes 1 μm high and 2.5 μm wide conical SiO₂ structures spaced at a 3 μm period.

### Implementation Example 3

### A Metal Composite Substrate Comprising a MoCu Alloy Layer and a GaN Layer Bonded with Au—Au Bonds

In the first steps, as shown in FIG. 8A, a GaN mono crystal thin film 2′ is epitaxially grown on a 2 inch 430 μm thick sapphire substrate 5 using MOCVD. The GaN mono crystal thin film 2′ is about 4 μm in thickness.

In the second steps, a 1 μm layer of SiO₂ thin film is grown on the surface of the GaN mono crystal thin film 2′ using PECVD technology. The SiO₂ thin layer is then patterned with lithography and dry etched into periodic conical structures 4′ spaced by a period of about 3 μm, as shown in FIG. 8A. The conical structures 4′ have a base diameter of about 2.5 μm and a height about 1 μm. The surface of the GaN mono crystal thin film 2′ is exposed in the space between the conical structures 4′. The periodic conical structures 4′ form as a reflective layer 4.

In the third steps, as shown in FIG. 8B, a GaN crystal layer is continuously grown using HVPE technology on the surface of the GaN mono crystal thin film 2′ and the reflective layer 4 composed of periodic conical structures 4′. The newly grown GaN crystal and the GaN mono crystal thin film 2′ together forms a mono-crystalline GaN layer 2 having a total thickness of about 10 μm. The reflective layer 4 is embedded inside the mono-crystalline GaN layer 2.

In the fourth steps, as shown in FIG. 8C, the surface of the mono-crystalline GaN layer 2 is bonded with a 2 inch 400 μm thick Si substrate 6 by an instant adhesive. The Si substrate 6 is used as a transfer and support substrate. The sapphire substrate 5 is then lifted off by laser lift-off technology, leaving the mono-crystalline GaN layer 2 bonded to the Si substrate 6.

In the fifth steps, a 1 μm Au layer is deposited simultaneously on the surfaces of the mono-crystalline GaN layer 2 and the Si substrate 6, and the surfaces of a separate 150 μm thick MoCu alloy layer (substrate) 1. The MoCu alloy layer 1 is then bonded to the surface of the mono-crystalline GaN layer 2 via Au—Au bonding, as shown in FIG. 8D, at 300° C. under a pressure of 5 tons for through 15 minutes. After bonding, the instant adhesive is carbonized at high temperature, which allows Si substrate 6 to separate from GaN/MoCu composite substrate.

At last, as shown in FIG. 8D, after surface cleaning, a composite substrate is obtained which includes a 150 μm thick MoCu alloy layer 1 with a Mo:Cu mass ratio of 20:80. The MoCu alloy layer 1 is bonded with a layer of 10 μm thick mono-crystalline GaN layer 2 by Au—Au bond, wherein the bonding layer 3 is 2 μm in thickness. The reflective layer 4 is embedded in the mono-crystalline GaN layer 2 and is at a 4 μm distance from the bonding layer 3. The reflective layer 4 includes 1 μm high and 2.5 μm wide conical SiO₂ structures spaced at a 3 μm period.

### Implementation Example 4

### A Metal Composite Substrate Comprising a MoCu Alloy Layer and a GaN Layer Bonded with Ni—Ni Bonds

In the first steps, a mono-crystalline GaN layer 2 is epitaxially grown on a 2 inch 430 μm thick sapphire substrate 5 using MOCVD. The mono-crystalline GaN layer 2 is about 4 μm in thickness.

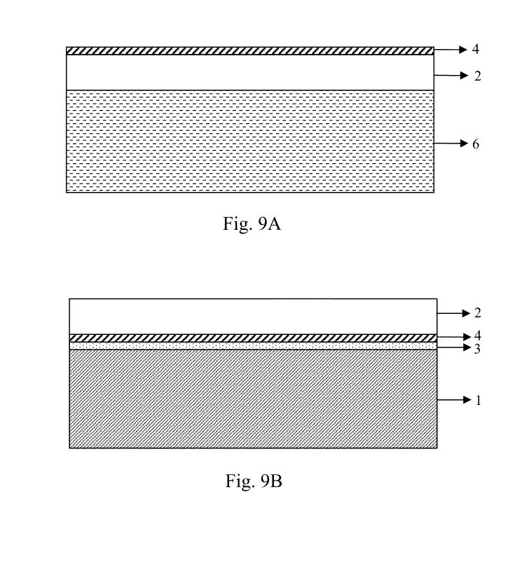

In the second steps, as shown in FIG. 9A, the surface of the mono-crystalline GaN layer 2 is bonded with a 2 inch 400 μm thick Si substrate 6 by an instant adhesive. The Si substrate 6 is used as a transfer and support substrate. The sapphire substrate 5 is then lifted off by laser lift-off technology, leaving the mono-crystalline GaN layer 2 bonded to the Si substrate 6.

In the third steps, a reflective layer 4 if formed by depositing a 200 nm thick Pd metal layer on the surface of the mono-crystalline GaN layer 2 on the Si substrate 6, as shown in FIG. 9A.

In the fourth steps, as shown in FIG. 9A, a 2 μm Ni is deposited simultaneously on the surfaces of the reflective layer 4 and the Si substrate 6, and the surfaces of a separate 150 μm thick MoCu alloy layer (substrate) 1. The MoCu alloy layer (substrate) 1 is bonded at 800°, under a 15 ton pressure, for 15 minutes to the reflective layer 4 with a Ni bonding layer 3 in between. After bonding, the instant adhesive is carbonized at high temperature, which allows Si substrate 6 to separate from GaN/MoCu composite substrate.

At last, as shown in FIG. 9B, after surface cleaning, a composite substrate is obtained which includes a 150 μm thick MoCu alloy layer 1 with a Mo:Cu mass ratio of 20:80. The MoCu alloy layer 1 is bonded by Ni—Ni bond to the reflective layer 4 which is bonded to a 4 μm thick mono-crystalline GaN layer 2. The bonding layer 3 is 4 μm in thickness.

### Implementation Example 5

### A Composite Substrate Comprising a Si Substrate and a GaN Layer Bonded by Van Der Waals Force

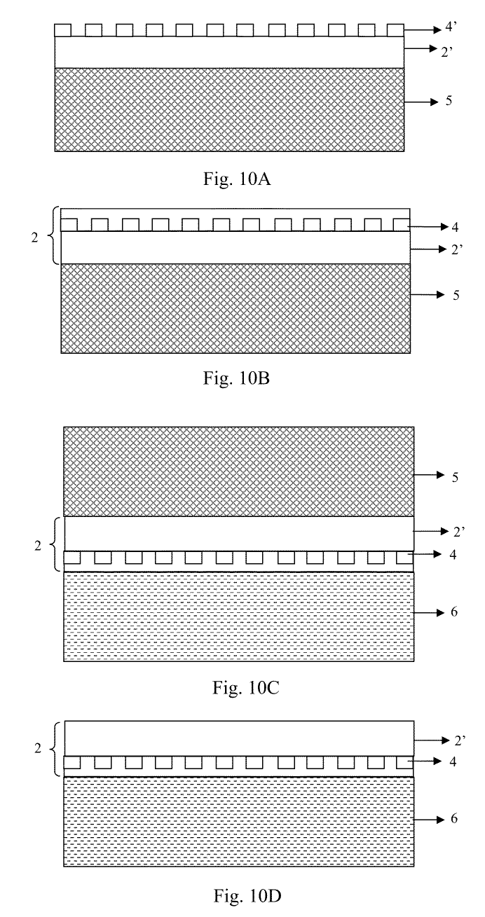

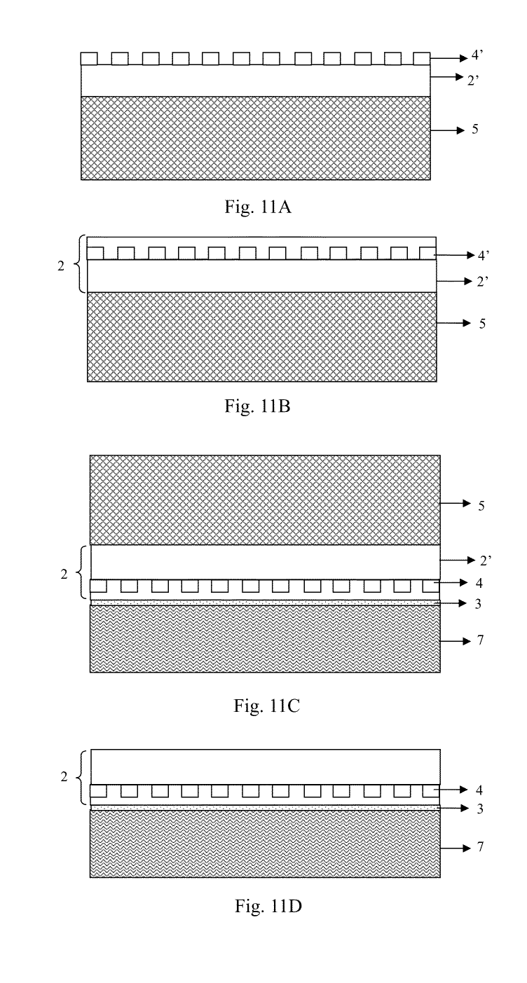

In the first steps, as shown in FIG. 10A, a GaN mono crystal thin film is epitaxially grown on a 2 inch 430 μm thick sapphire substrate 5 using MOCVD. The GaN mono crystal thin film 2′ is about 4 μm in thickness.

In the second steps, a GaN crystal layer 2′ is continuously grown using HVPE technology on the surface of the GaN mono crystal thin film until the total thickness of the GaN crystal reaches 46 μm.

In the third steps, a 1 μm thick SiO₂ thin film is grown by PECVD technology on the surface of the GaN crystal layer 2′. The SiO₂ thin layer is then patterned with lithography and dry etched into periodic cylindrical structures 4′ spaced by a period of about 3 μm, as shown in FIG. 10A. The cylindrical structures 4′ have a base diameter of about 2 μm and a height about 1 μm. The surface of the GaN crystal layer 2′ is exposed in the space between the cylindrical structures 4′. The periodic cylindrical structures 4′ form a reflective layer 4.

In the fourth steps, as shown in FIG. 10B, a GaN crystal layer is continuously grown using HVPE technology on the surface of the GaN crystal layer 2′ and the reflective layer 4 composed of periodic cylindrical structures 4′. The newly grown GaN crystal and the GaN mono crystal thin film 2′ together forms a mono-crystalline GaN layer 2 having a total thickness of about 50 μm. The reflective layer 4 is embedded inside the mono-crystalline GaN layer 2.

In the fifth steps, the surface of the mono-crystalline GaN layer 2 is bonded with a 2 inch 400 μm thick Si substrate 6 by a van der Waals force, at 900° C. under pressure of 20 tons for through 30 minutes, forming a sapphire/GaN/Si assembly, as shown in FIG. 10C.

In the sixth steps, the sapphire substrate 5 is then lifted off by laser lift-off technology, leaving the mono-crystalline GaN layer 2 bonded to the Si substrate 6, as shown in FIG. 10D.

At last, as shown in FIG. 10D, a composite substrate is obtained which includes a layer of 400 μm thick Si substrate 6, bonded with a layer of 50 μm thick GaN mono crystal 2 by van der Waals force. The reflective layer 4 is embedded in the mono-crystalline GaN layer 2 and is at a 4 μm distance from the bonding layer 3. The reflective layer 4 includes 1 μm high and 2 μm wide cylindrical SiO₂ structures spaced at a 3 μm period.

### Implementation Example 6

### A Metal Composite Substrate Comprising a SiC Layer and a GaN Layer Bonded with Pd—Pd Bonds

In the first steps, as shown in FIG. 8A, a GaN mono crystal thin film 2′ is epitaxially grown on a 2 inch 430 μm thick sapphire substrate 5 using MOCVD. The GaN mono crystal thin film 2′ is about 4 μm in thickness.

In the second steps, a 1 μm layer of SiO₂ thin film is grown on the surface of the GaN mono crystal layer using PECVD technology. The SiO₂ thin layer is then patterned with lithography and dry etched into periodic conical structures 4′ spaced by a period of about 3 μm, as shown in FIG. 8A. The conical structures 4′ have a base diameter of about 2.5 μm and a height about 1 μm. The surface of the GaN mono crystal thin film 2′ is exposed in the space between the conical structures 4′. The periodic conical structures 4′ form as a reflective layer 4.

In the third steps, as shown in FIG. 8B, a GaN crystal layer is continuously grown using HVPE technology on the surface of the GaN mono crystal thin film 2′ and the reflective layer 4 composed of periodic conical structures 4′. The newly grown GaN crystal and the GaN mono crystal thin film 2′ together forms a mono-crystalline GaN layer 2 having a total thickness of about 10 μm. The reflective layer 4 is embedded inside the mono-crystalline GaN layer 2.

In the fourth steps, as shown in FIG. 8C, the surface of the mono-crystalline GaN layer 2 is bonded with a 2 inch 400 μm thick Si substrate 6 by an instant adhesive. The Si substrate 6 is used as a transfer and support substrate. The sapphire substrate 5 is then lifted off by laser lift-off technology, leaving the mono-crystalline GaN layer 2 bonded to the Si substrate 6.

In the fifth steps, a 1 μm Pd layer is deposited simultaneously on the surfaces of the mono-crystalline GaN layer 2 and the Si substrate 6, and the surfaces of a separate 150 μm thick SiC alloy layer (substrate) 1. The SiC alloy layer 1 is then bonded to the surface of the mono-crystalline GaN layer 2 via Pd—Pd bonding, as shown in FIG. 8D, at 800° C. under a pressure of 8 tons for through 15 minutes. After bonding, the instant adhesive is carbonized at high temperature, which allows Si substrate 6 to separate from GaN/SiC composite substrate.

At last, as shown in FIG. 8D, after surface cleaning, a composite substrate is obtained which includes a 150 μm thick SiC alloy layer. The SiC alloy layer 1 is bonded with a layer of 10 μm thick mono-crystalline GaN layer 2 by Pd—Pd bonds, wherein the bonding layer 3 is 2 μm in thickness. The reflective layer 4 is embedded in the mono-crystalline GaN layer 2 and is at a 4 μm distance from the bonding layer 3. The reflective layer 4 includes 1 μm high and 2.5 μm wide conical SiO₂ structures spaced at a 3 μm period.

### Implementation Example 7

### A Metal Composite Substrate Comprising a AlSi Layer and a GaN Layer Bonded with Au—Au Bonds

In the first steps, as shown in FIG. 8A, a GaN mono crystal thin film 2′ is epitaxially grown on a 2 inch 430 μm thick sapphire substrate 5 using MOCVD. The GaN mono crystal thin film 2′ is about 6 μm in thickness.

In the second steps, a 1 μm layer of SiO₂ thin film is grown on the surface of the GaN mono crystal thin film 2′ using PECVD technology. The SiO₂ thin layer is then patterned with lithography and dry etched into periodic conical structures 4′ spaced by a period of about 3 μm, as shown in FIG. 11A. The cylindrical structures 4′ have a diameter of about 2 μm and a height about 1 μm. The surface of the GaN mono crystal thin film 2′ is exposed in the space between the cylindrical structures 4′. The periodic cylindrical structures 4′ form as a reflective layer 4.

In the third steps, as shown in FIG. 11B, a GaN crystal layer is continuously grown using HVPE technology on the surface of the GaN mono crystal thin film 2′ and the reflective layer 4 composed of periodic conical structures 4′. The newly grown GaN crystal and the GaN mono crystal thin film 2′ together forms a mono-crystalline GaN layer 2 having a total thickness of about 10 μm. The reflective layer 4 is embedded inside the mono-crystalline GaN layer 2.

In the fourth steps, a 1 μm Au layer is deposited simultaneously on the surfaces of the mono-crystalline GaN layer 2 and the sapphire substrate 5, and the surfaces of a separate 200 μm thick AlSi alloy layer (substrate) 7. The AlSi alloy layer 7 is then bonded to the surface of the mono-crystalline GaN layer 2 via Au—Au bonding in a bonding layer 3, as shown in FIG. 11C, at 300° C. under a pressure of 5 tons for through 15 minutes.

In the fifth steps, after bonding, the sapphire substrate is lifted off by laser lift-off technology, leaving a composite substrate with GaN/AlSi bonded by the bonding layer 3, as shown in FIG. 11D.

At last, as shown in FIG. 11D, after surface cleaning, a composite substrate is obtained which includes a 200 μm thick AlSi layer 7 with a Al:Si mass ratio of 30:70. The AlSi layer 7 is bonded with a layer of 10 μm thick mono-crystalline GaN layer 2 by Au—Au bond, wherein the bonding layer 3 is about 4 μm in thickness. The reflective layer 4 is embedded in the mono-crystalline GaN layer 2. The reflective layer 4 includes 1 μm high and 2 μm wide cylindrical SiO₂ structures spaced at a 3 μm period.

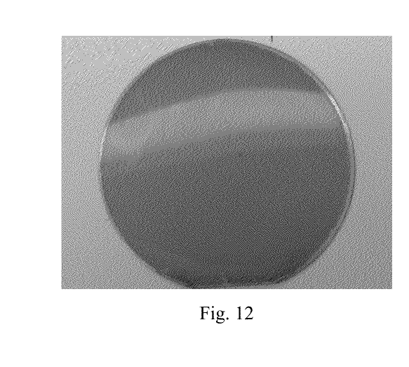

A photograph of an exemplified composite substrate prepared by one of the presently disclosed methods is shown in FIG. 12. The composite substrate includes a mono-crystalline GaN layer bonded with a metal substrate.

While this document contains many specifics, these should not be construed as limitations on the scope of an invention that is claimed or of what can be claimed, but rather as descriptions of features specific to particular embodiments. Certain features that are described in this document in the context of separate embodiments can also be implemented in combination in a single embodiment. Conversely, various features that are described in the context of a single embodiment can also be implemented in multiple embodiments separately or in any suitable sub-combination. Moreover, although features can be described above as acting in certain combinations and even initially claimed as such, one or more features from a claimed combination can in some cases be excised from the combination, and the claimed combination can be directed to a sub-combination or a variation of a sub-combination.

It will thus be seen that the objects of the present invention have been fully and effectively accomplished. Its embodiments have been shown and described for the purpose of illustrating the functional and structural principles of the present invention and is subject to change without departure from such principles. Therefore, this invention includes all modifications encompassed within the spirit and scope of the following claims.

1. A method for preparing a composite substrate for GaN growth, comprising the steps of:
1a) growing a GaN monocrystal epitaxial layer on a sapphire substrate;
1b) bonding the GaN monocrystal epitaxial layer on the sapphire substrate onto a temporary substrate with an epoxy-type instant adhesive;
lifting off the sapphire substrate by laser lift-off method; and
1c) bonding the GaN monocrystal epitaxial layer on the temporary substrate with a thermally and electrically conducting substrate with a melting point greater than 1000° C., wherein the epoxy-type instant adhesive is to be carbonized at high temperature,
shedding the temporary substrate; and
obtaining a composite substrate in which the GaN monocrystal epitaxial layer having gallium polarity facing up is bonded to the thermally and electrically conducting substrate.

2. The method of claim 1, wherein the step a) comprises growing GaN monocrystal epitaxial layer on the sapphire substrate, wherein the step b) comprises;
transferring GaN monocrystal epitaxial layer from the sapphire substrate onto the temporary substrate; and
depositing a metal reflecting layer on the surface of GaN monocrystal epitaxial layer, before step 1c).

3. The method of claim 1, wherein the step a) comprises growing a GaN monocrystal epitaxial layer comprises:
growing a layer of GaN, growing a layer of reflecting layer materials;
preparing the layer of reflecting layer materials into micron-scale or nano-scale periodic structures by lithography and dry etching technologies; and
exposing the GaN surface in the spacing between the periodic structures, and growing GaN monocrystal continuously to a predetermined thickness, and then conducting step 1b), wherein the reflecting layer materials has a refractive index different from that of GaN, wherein the reflecting layer has a melting point greater than 1000° C.

4. The method of claim 3, wherein the reflecting layer material comprises SiO₂ or SiN.

5. The method of claim 1, wherein the sapphire substrate in step 1a) is a patterned sapphire substrate, wherein the patterned sapphire substrate is obtained by preparing micron-scale or nano-scale periodic structural patterns on the surface of the sapphire substrate by lithography lift-off.

6. The method of claim 1, wherein the bonding step in step 1c) is rigid bonding or flexible medium bonding, wherein the rigid bonding is based on Van der Waals bonding the GaN epitaxial layer on the temporary substrate with a thermally and electrically conducting substrate directly, at 500˜900° C., under a pressure of 3 tons per square inch to 10 tons per square inch, with the coefficient of thermal expansion difference between the materials of the thermally and electrically conducting layer and GaN is within 10% during the rigid bonding,
wherein the flexible medium bonding comprises first depositing bonding metal on the surface to be bonded, and then bonding the GaN epitaxial layer on the temporary substrate with a thermally and electrically conducting substrate, at 200˜900° C., under a pressure of 1 tons per square inch to 5 tons per square inch.

7. A method for preparing a composite substrate for GaN growth, comprising the steps of:
2a) growing a GaN monocrystal epitaxial layer on a sapphire substrate;
2b) bonding the epitaxial layer on the sapphire substrate with a thermally and electrically conducting layer with a melting point greater than 1000° C.; and
2c) lifting off the sapphire substrate by laser lift-off method, obtaining a composite substrate with nitrogen polarity facing up is with the GaN monocrystal epitaxial layer bonded with the thermally and electrically conducting layer.

8. The method of claim 7, further comprising:
after growing the GaN monocrystal epitaxial layer on the sapphire substrate in step 2a), depositing a metal reflecting layer on the surface of the GaN monocrystal, and then conducting step 2b).

9. The method of claim 7, wherein the step of growing a GaN monocrystal epitaxial layer in step 2a) comprises:
growing a layer of GaN;
growing a layer of reflecting layer materials;
preparing the layer of reflecting layer material into micron-scale or nano-scale periodic structures by lithography and dry etching;
requiring to expose the GaN surface at the spacing of these structures;
growing GaN monocrystal continuously to a predetermined thickness; and
conducting step 2b), wherein the reflecting layer materials has a refractive index different from that of GaN, wherein the reflecting layer has a melting point greater than 1000° C.

10. The method of claim 9, wherein the reflecting layer material comprises SiO₂ or SiN.

11. The method of claim 7, wherein the bonding step in step 2b) comprises rigid bonding or flexible medium bonding,
wherein the rigid bonding includes Van der Waals bonding the GaN epitaxial layer on the sapphire substrate with a thermally and electrically conducting substrate directly, at 500˜900° C., under a pressure of 3 tons per square inch to 10 tons per square inch, with the coefficient of thermal expansion difference between the materials of the thermally and electrically conducting layer and GaN is within 10% during the rigid bonding,
wherein the flexible medium bonding includes first depositing bonding metal on the surface to be bonded, and then bonding the GaN monocrystal epitaxial layer on the sapphire substrate with a thermally and electrically conducting substrate, at 200˜900° C., under a pressure of 1 tons per square inch to 5 tons per square inch.

12. The method of claim 7, wherein the materials for the thermally and electrically conducting layer is selected from the group consisting of W, Ni, Mo, Pd, Au, Cr, or alloy of one or more above metals with Cu, or Si crystal, SiC crystal, and AlSi crystal.
